(19) United States
(12) Patent Application Publication
(10) Pub. No.: US 2021/0104385 A1
(43) Pub. Date: Apr. 8, 2021

(54) SUBSTRATE SUPPORT PEDESTAL AND PLASMA PROCESSING APPARATUS

(71) Applicant: Tokyo Electron Limited, Tokyo (JP)

(72) Inventors: Ryou SON, Miyagi (JP); Tomoyuki TAKAHASHI, Miyagi (JP); Sinya SASAKI, Miyagi (JP); Masaru SASAKI, Miyagi (JP)

(21) Appl. No.: 17/034,265

(22) Filed: Sep. 28, 2020

(30) Foreign Application Priority Data
Oct. 4, 2019 (JP) 2019-183871

(51) Int. Cl. H01J 37/32

(52) U.S. Cl. CPC H01J 37/32724; H01J 2237/2001; H01J 2237/334

(57) ABSTRACT

There is provided a substrate support pedestal including: a first metallic member having a recess formed in an upper portion of the first metallic member; a second metallic member provided on the first metallic member and configured to seal the recess; a substrate support part provided on the second metallic member; and one or more thermoelectric elements disposed in the recess, wherein the recess is filled with a heat transfer medium.

### CROSS-REFERENCE TO RELATED APPLICATION

This application is based upon and claims the benefit of priority from Japanese Patent Application No. 2019-183871, filed on Oct. 4, 2019, the entire contents of which are incorporated herein by reference.

### TECHNICAL FIELD

Exemplary embodiments of the present disclosure relate to a substrate support pedestal and a plasma processing apparatus.

### BACKGROUND

Patent Document 1 discloses a technique related to a stage that enables temperature control in a wide temperature band. The stage has a hollow ceramic housing formed through sintering, a heating element or a heat exchange element (Peltier element), a cooling plate built in the housing, and a placement portion. The heating element or the heat exchange element is built in the housing that is provided with the stage that enables temperature control in a wide temperature range. The placement portion is formed on the housing, and a substrate is placed on a placement surface. The heating element or the heat exchange element, and the cooling plate are bonded with each other in a compression manner.

Patent Document 2 discloses a technique related to a substrate support of a temperature-controlled semiconductor. The substrate support has a plurality of thermoelectric modules, a temperature sensor, an electricity supply interface, and a controller. The thermoelectric module is in contact with a substrate support surface that includes electrodes biased by a radio frequency, in a heat transfer manner. The temperature sensor acquires temperature information in the central portion and the edge area of the substrate. The electricity supply interface is connected to the plurality of thermoelectric modules and controls the temperature of the substrate support surface in the central portion and the edge area of the substrate. The controller controls current to be supplied from the electricity supply interface to the plurality of thermoelectric modules in the central portion and the edge area of the substrate based on the temperature information acquired by the temperature sensor.

### PRIOR ART DOCUMENT

### Patent Document

Patent Document 1: Japanese Laid-Open Patent Publication No. 2016-082077
Patent Document 2: Japanese Laid-Open Patent Publication No. 2000-508119

### SUMMARY

According to one embodiment of the present disclosure, there is provided a substrate support pedestal including: a first metallic member having a recess formed in an upper portion of the first metallic member; a second metallic member provided on the first metallic member and configured to seal the recess; a substrate support part provided on the second metallic member; and one or more thermoelectric elements disposed in the recess, wherein the recess is filled with a heat transfer medium.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view illustrating an example of a main configuration of a plasma processing apparatus according to an exemplary embodiment.

FIG. 2 is a view illustrating an example of a main configuration of a substrate support pedestal according to an exemplary embodiment.

FIG. 3 is a view illustrating another example of the main configuration of the substrate support pedestal according to an exemplary embodiment.

FIG. 4 is a view partially illustrating a configuration of a support part illustrated in FIG. 2.

FIG. 5 is a view for explaining an arrangement of one or more thermoelectric elements SP1a.

FIG. 6 is a flowchart illustrating a method according to an exemplary embodiment.

### DETAILED DESCRIPTION

Hereinafter, various exemplary embodiments will be described. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In an exemplary embodiment, a substrate support pedestal is provided. The substrate support pedestal has a first member (or first metallic member), a second member (or first metallic member), a substrate support part, and one or more thermoelectric elements. The first member has a recess formed in an upper portion thereof and is made of metal. The second member is provided on the first member to seal the recess, and is made of metal. The substrate support part is provided on the second member. The thermoelectric elements are arranged in the recess. The recess is filled with a heat transfer medium.

In an exemplary embodiment, the one or more thermoelectric elements are distributed along the substrate support part. The one or more thermoelectric elements may be arranged at uniform intervals in the circumferential direction of the substrate support part.

In an exemplary embodiment, the one or more thermoelectric elements may be densely arranged on the peripheral side, compared to the center of the substrate support part.

In an exemplary embodiment, the first member further includes a flow path through which a temperature control medium flows. The flow path is switchably connected to a first chiller or a second chiller. The temperature control medium supplied from the first chiller and the temperature control medium supplied from the second chiller have different temperatures.

In an exemplary embodiment, the substrate support part further includes a heater electrode.

In an exemplary embodiment, the heater electrode is provided between the substrate support part and the one or more thermoelectric elements.

In an exemplary embodiment, the heat transfer medium is a liquid.

In an exemplary embodiment, the heat transfer medium is an inert gas.

In an exemplary embodiment, the first member includes one or more storage areas. The one or more storage areas are arranged along the substrate support part. The one or more thermoelectric elements is stored in the one or more storage areas, respectively, together with the heat transfer medium.

In an exemplary embodiment, the second member is provided between the substrate support part and one or more recesses. The one or more recesses are sealed by the second member.

In an exemplary embodiment, the thermoelectric elements are fixed to the first member using a heat-conductive adhesive inside the recess.

In an exemplary embodiment, the one or more thermoelectric elements are electrically connected in series in the circumferential direction of the substrate support part.

In an exemplary embodiment, a plasma processing apparatus is provided. The plasma processing apparatus includes the substrate support pedestal of one of the above embodiments.

Hereinafter, various exemplary embodiments will be described in detail with reference to the drawings. In each of the drawings, the same or corresponding parts will be denoted by the same reference numerals.

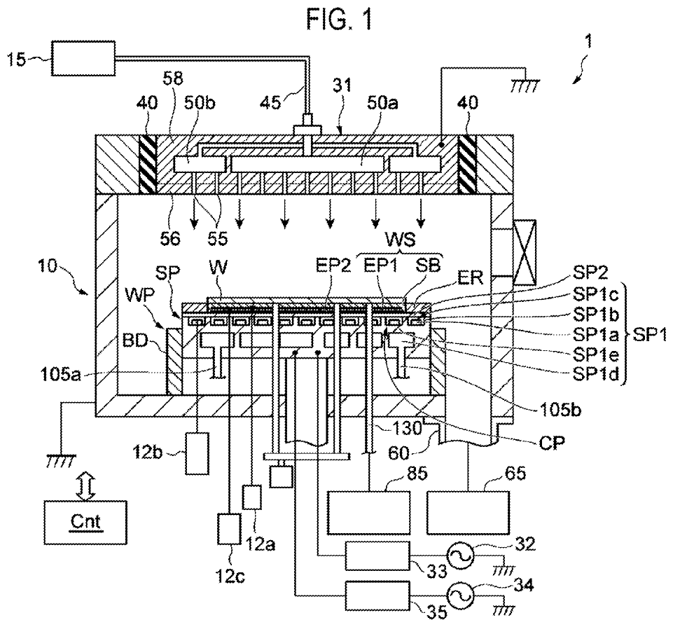

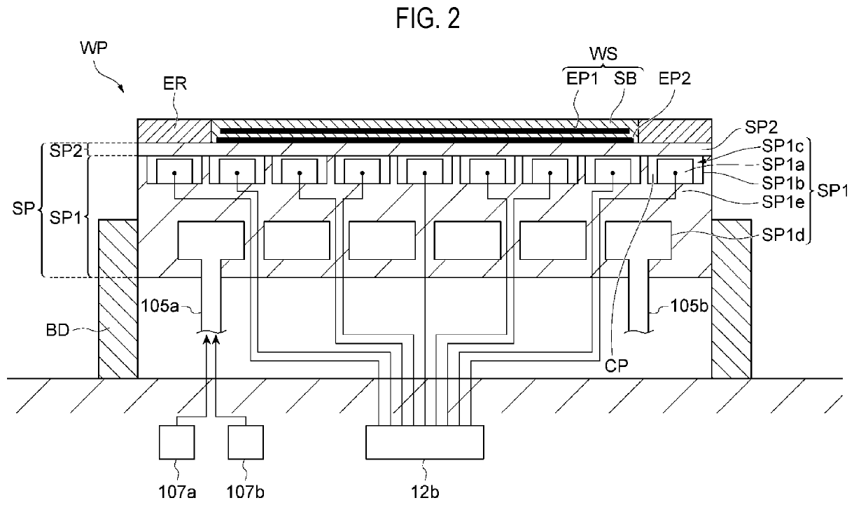

A configuration of a plasma processing apparatus 1 according to an exemplary embodiment will be described mainly with reference to FIGS. 1 and 2. The plasma processing apparatus 1 illustrated in FIG. 1 is a capacitively coupled plasma processing apparatus. A substrate support pedestal WP according to the embodiment illustrated in FIG. 1 may be applied to various plasma processing apparatuses, such as an inductively coupled plasma processing apparatus, without being limited to the capacitively coupled plasma processing apparatus.

The plasma processing apparatus 1 includes a chamber 10. The chamber 10 has, for example, a cylindrical shape. A surface of the chamber 10 may be made of, for example, alumite-treated (anodized) aluminum. The chamber 10 is grounded.

The substrate support pedestal WP is provided inside the chamber 10. The substrate support pedestal WP is installed in the bottom portion of the chamber 10. The substrate support pedestal WP has a housing BD. The housing BD is, for example, a hollow cylindrical member formed through sintering. A material of the housing BD is, for example, ceramic. The substrate support pedestal WP includes a substrate support part WS, a metal support part SP, a heater EP2, and one or more thermoelectric elements SP1a. The thermoelectric elements SP1a include a plurality of elements in each of which a P-type thermoelectric material and an N-type thermoelectric material are connected in series. The elements are capable of controlling the side of the substrate support part to a high temperature or conversely to a low temperature by controlling the magnitude and direction of DC current applied to the elements. Each thermoelectric element has a characteristic that when one of upper and lower surfaces of the thermoelectric element has a high temperature (heat radiation), the other has a low temperature (heat absorption). The thermoelectric element has good responsiveness.

The substrate support part WS is configured to support a semiconductor wafer (hereinafter, referred to as a “substrate W”). The substrate support part WS is provided on the support part SP. FIGS. 1 to 4 illustrate an example in which the substrate support part WS is an electrostatic chuck. An edge ring ER may be arranged on the substrate support part WP so as to surround the substrate support part WS.

The electrostatic chuck includes a dielectric body SB and an attraction electrode EP1 provided inside the dielectric body SB.

A DC power supply 12a is connected to the attraction electrode EP1. The substrate W is attracted by virtue of an electrostatic force generated by applying a voltage from the DC power supply 12a to the attraction electrode EP1.

The heater EP2 is provided between the attraction electrode EP1 and the one or more thermoelectric elements SP1a. In an example, the heater EP2 may be provided inside the dielectric body SB. In another example, the heater EP2 may be provided between the substrate support part WS and the support part SP. In yet another example, the heater EP2 may be embedded in the support part SP.

A heater power supply 12c is connected to the heater EP2. The heater EP2 is configured to generate heat by a DC current applied from the heater power supply 12c.

The support part SP has a first member SP1 and a second member SP2 provided on the first member SP1. The first member SP1 and the second member SP2 are made of a metal having good heat conductivity, for example, aluminum. Since the second member SP2 is made of metal, it is possible to achieve good heat uniformity in the plane of the substrate W. The first member SP1 and the second member SP2 may extend not only below the substrate support part WS, but also below the edge ring ER. The substrate support part WS is provided on the second member SP2. The substrate support part WS may be bonded to an upper surface of the second member SP2 (a surface of the second member SP2 opposite the side of the first member SP1) using an adhesive. In another example, the substrate support part WS may be fixed to the second member SP2 by a mechanical means such as a clamp.

The first member SP1 includes one or more storage areas SP1b. In addition, one or more recesses CP are formed in an upper portion of the first member SP1. In this embodiment, the case in which the recesses CP are integrally formed in the upper portion of the first member SP1 is illustrated, but the recesses may be formed by a separate member and the first member SP1. The second member SP2 is provided between the one or more storage areas SP1b and the substrate support part WS. Each of the one or more storage areas SP1b is defined by each of the one or more recesses CP and the second member SP2 and is hermetically sealed. The recesses CP are sealed by the second member SP2 so that the storage areas SP1b are sealed in air-tight manner or a liquid-tight manner. In each of the one or more storage areas SP1b, each of the one or more thermoelectric elements SP1a is stored together with the heat transfer medium SP1c. In an example, the one or more storage areas SP1b may be arranged along the substrate support part WS.

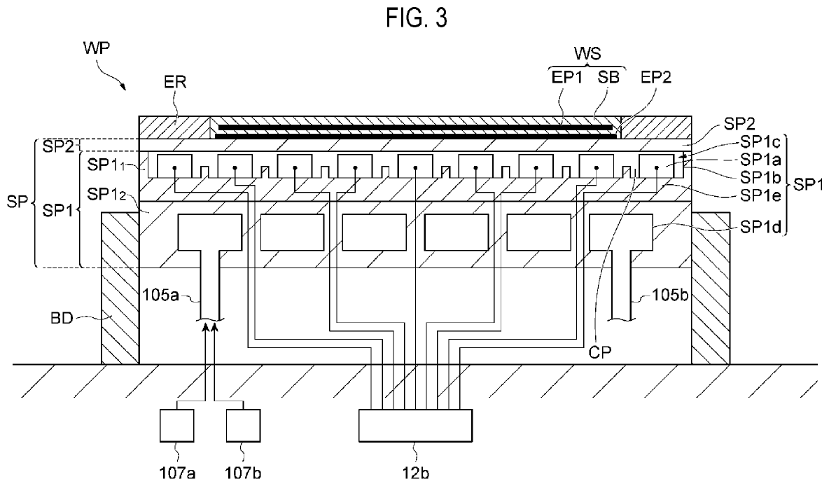

In an embodiment, the one or more thermoelectric elements SP1a is arranged in the one or more recesses CP, respectively. The recesses CP are filled with the heat transfer medium SP1c and sealed with the second member SP2. In another aspect, as illustrated in FIG. 3, areas in which the thermoelectric elements SP1a are arranged may be partitioned in a common recess CP, and the thermoelectric elements SP1a may be arranged in the partitioned areas, respectively. The recesses CP are filled with the heat transfer medium SP1c and sealed with the second member SP2. Then, in any aspect, a gap between each thermoelectric element SP1a and the second member SP2 may be provided sufficiently narrow or the thermoelectric elements SP1a and the second member SP2 are in contact with each other such that the heat conduction between the thermoelectric elements SP1a and the second member SP2 is good. In addition, the first member SP1 illustrated in FIG. 3 has a first area SP11 and a second area SP12. The first area SP11 is provided on the second area SP12. One or more recesses CP are provided in the first area SP11, and a flow path SP1d is provided in the second area SP12. The first area SP11 and the second area SP12 may be bonded to each other with an adhesive having heat conductivity.

The heat transfer medium SP1c may be a heat-conductive liquid or an inert gas. Examples of the heat transfer medium SP1c include pure water or a He gas. The electric conductivity of the heat transfer medium SP1c is preferably low. In an example, the thermoelectric element SP1a is fixed inside the first member SP1 using a heat-conductive adhesive. The adhesive may include a filler. In another example, the thermoelectric elements SP1a may be arranged in the support part SP (on inner surfaces of the recesses CP) without using an adhesive.

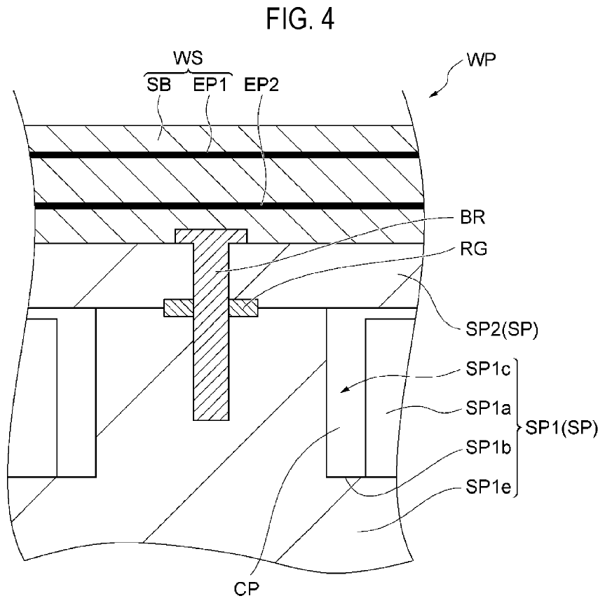

As illustrated in FIG. 4, the second member SP2 and a main body SP1e of the first member SP1 are fixed to each other via a fixing element BR such as a screw and a sealing material such as an O-ring RG. The fixing element BR has good heat conductivity and electrical conductivity.

In addition, in another example, the second member SP2 and the main body SP1e may be bonded to each other using an adhesive having good heat conductivity.

A DC power supply 12b is connected to each of the one or more thermoelectric elements SP1a. The thermoelectric elements SP1a performs cooling or heating depending on an orientation of current applied from the DC power supply 12b.

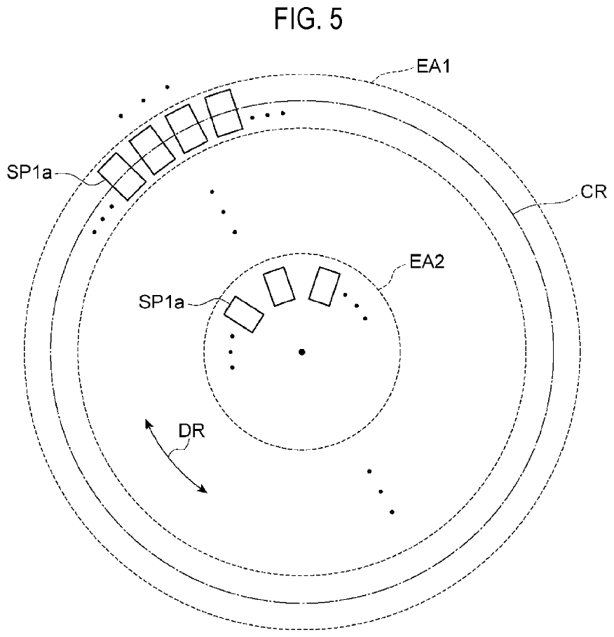

As illustrated in FIG. 5, the one or more thermoelectric elements SP1a are electrically connected in series in a circumferential direction DR of the substrate support part WS. More specifically, the one or more thermoelectric elements SP1a are connected in series for each circumferential direction DR of the substrate support part WS. Therefore, the current supplied to the thermoelectric elements SP1a can be controlled for each circumferential direction DR. In addition, it becomes possible to detect disconnection for each circumferential direction DR.

The one or more thermoelectric elements SP1a are dispersedly arranged along the substrate support part WS. As illustrated in FIG. 5, the one or more thermoelectric elements SP1a may be arranged at uniform intervals in the circumferential direction DR of the substrate support part WS.

The one or more thermoelectric elements SP1a may be arranged more densely (higher density) on the peripheral side than a central portion CE of the substrate support part WS. A first area EA1 and a second area EA2 illustrated in FIG. 5 are examples of areas in which the thermoelectric elements SP1a are arranged. The thermoelectric elements SP1a may also be arranged areas other than the first area EA1 and the second area EA2.

The first area EA1 is an area that extends along a peripheral edge CR of the substrate support part WS below the peripheral edge CR. The second area EA2 is an area below the central portion CE of the substrate support part WS and covers the central portion CE.

The one or more thermoelectric elements SP1a may be arranged more densely (higher density) in the first area EA1 than in the second area EA2.

The above-mentioned “more densely (higher density)” means that, for example, a ratio of a length of the circumference (e.g., the peripheral edge CR) extending along the circumferential direction DR to a length occupied by the one or more thermoelectric elements SP1a arranged on the circumference is high.

In addition, a first ratio of an area occupied by the one or more thermoelectric elements SP1a arranged in the first area EA1 to the area of the first area EA1 and a second ratio of an area occupied by the one or more thermoelectric elements SP1a arranged in the second area EA2 to the area of the second area EA2 are considered. In this case, “more densely (high density)” may mean that, for example, the first ratio is higher than the second ratio.

The thermoelectric elements SP1a may be arranged not only below the substrate support part WS, but also below the edge ring ER.

The first members SP1 include the flow path SP1d through which temperature control mediums (heating medium and cooling medium) flow. The flow path SP1d is switchably connected to the first chiller 107a or the second chiller 107b.

A temperature of the temperature control medium supplied from the first chiller 107a and a temperature of the temperature control medium supplied from the second chiller 107b differ from each other. For example, in the present embodiment, the temperature control medium supplied from the first chiller 107a is a heating medium, and the temperature control medium supplied from the second chiller 107b is a cooling medium. In this case, the temperature of the temperature control medium (heating medium) supplied from the first chiller 107a is controlled to, for example, 80 degrees C., and the temperature of the temperature control medium (cooling medium) supplied from the second chiller 107b is controlled to, for example, −30 degrees C.

The temperature control mediums (heating medium and cooling medium) circulate from an inlet 105a of the flow path SP1d through the flow path SP1d of the support part SP, exit from an outlet 105b of the flow path SP1d, and return again to the first chiller 107a or the second chiller 107b.

In the substrate support pedestal WP described above, the temperature of the wafer W placed on the substrate support part WS is capable of being controlled in a wide temperature range by controlling the orientation of the current supplied to the one or more thermoelectric elements SP1a, the temperature of the temperature control medium flowing through the support part SP, and the temperature of the heater EP2.

Further, a first high-frequency power supply 32 for exciting plasma is connected to the substrate support pedestal WP via a first matcher 33. A second high-frequency power supply 34 suitable for drawing ions in the plasma into the substrate W is connected to the substrate support pedestal WP via a second matcher 35. The first high-frequency power supply 32 may be connected to a shower head 31 described below.

The shower head 31, which is an upper electrode having a ground potential, is provided on a ceiling portion of the chamber 10 via a dielectric body 40. Accordingly, a high-frequency power from the first high-frequency power supply 32 can be capacitively applied between the substrate support pedestal WP and the shower head 31.

The shower head 31 has an electrode plate 56 having a number of gas vent holes 55, and an electrode support 58 configured to detachably support the electrode plate 56. The gas source 15 is configured to supply gas into the shower head 31 through a gas supply pipe 45. The gas is introduced into the chamber 10 from a large number of gas vent holes 55 through diffusion chambers 50a and 50b arranged so as to correspond to two gas supply paths, respectively.

An exhaust pipe 60 that forms an exhaust port is provided in the bottom portion of the chamber 10. The exhaust pipe 60 is connected to an exhaust device 65. The exhaust device 65 has a vacuum pump such as a turbo molecular pump, a dry pump or the like, and is configured to depressurize an internal processing space of the chamber 10 to a preset level of vacuum, and to exhaust the gas inside the chamber 10 from the exhaust port of the exhaust pipe 60 to the outside of the chamber 10.

A heat transfer gas such as helium (He) supplied from a heat transfer gas source 85 may be supplied to a rear surface of the substrate W through a gas pipe 130. Accordingly, heat transfer from the rear surface of the substrate W to the support part SP is facilitated.

The interior of the chamber 10 is depressurized to a desired level of vacuum by the exhaust device 65.

A preset gas is introduced into the chamber 10 from the shower head 31 in the form of a shower. The high-frequency powers are applied to the substrate support pedestal WP from the first high-frequency power supply 32 and the second high-frequency power supply 34. Plasma is generated from the introduced gas by the high-frequency powers, and the substrate W is etched.

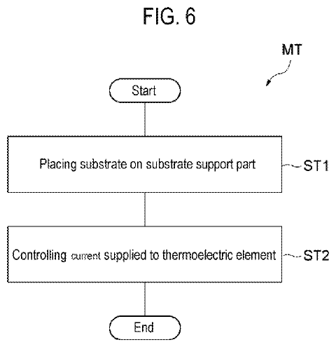

A controller Cnt includes a CPU, a ROM, a RAM, and the like, and comprehensively controls the operation of each part of the plasma processing apparatus 1 by executing a computer program stored in the ROM or the like. In particular, the controller Cnt executes a method MT illustrated in FIG. 6 by controlling the operations of the DC power supply 12b configured to supply the current to the thermoelectric elements SP1a, the heater power supply 12c configured to apply a voltage to the heater EP2, the first chiller 107a, and the second chiller 107b.

According to the configuration described above, the thermoelectric elements SP1a are thermally coupled to the metal support part SP via the heat transfer medium SP1c, and the support part SP is in contact with the substrate support part WS. The support part SP and the heat transfer medium SP1c have an excellent heat conductivity and good thermal responsiveness. Therefore, the effect of heat absorption and heat radiation by the thermoelectric elements SP1a satisfactorily exerted on the substrate support part WS. The temperature of the substrate W placed on the substrate support part WS is controlled with good responsiveness.

By combining the cooling (heat absorption) and heating (heat radiation) by the thermoelectric elements SP1a, the cooling and heating by the temperature control mediums flowing through the flow path SP1d, and the heating by the heater EP2, it is possible to control the temperature of the substrate support WP within a wide temperature range. It is possible to control the temperature of the substrate W to a lower temperature by causing the temperature control medium (cooling medium) to flow through the flow path SP1d and causing the thermoelectric elements SP1a to absorb heat. It is possible to control the temperature of the substrate W to a higher temperature by causing the temperature control medium (heating medium) to flow through the flow path SP1d and to be heated by the heater EP2.

The method MT according to an exemplary embodiment of a temperature control method will be described with reference to FIG. 6. The method MT includes steps ST1 and ST2. The method MT etches, for example, a multilayer film formed on the substrate W.

In step ST1, the controller Cnt places the substrate W on the substrate support pedestal WP. In step ST2 subsequent to step ST1, the controller Cnt controls the DC power supply 12b to supply current to the one or more thermoelectric elements SP1a arranged inside the first member SP1.

In step ST2, the controller Cnt controls the temperature of the substrate support pedestal according to the type of film to be etched. Specifically, the controller Cnt controls the current value to be supplied to the one or more thermoelectric elements SP1a, and the current value to be supplied to the heater EP2, and the chillers. Here, controlling the current value to be supplied to the one or more thermoelectric elements SP1a may include controlling not only the magnitude of the current, but also the orientation of the current. Further, controlling the temperature of the chillers may include switching the first chiller 107a and the second chiller 107b, in addition to controlling the temperature of a thermal medium.

A case in which the substrate support part WS is set to have a first temperature to etch a first film of the multilayer film, and after the first film is etched, the substrate support part WS is set to have a second temperature lower than the first temperature to etch a second film under the first film will be described as an example. The controller Cnt controls the heater power supply 12c to cause the heater EP2 to generate heat. Further, controller Cnt controls the first chiller 107a to circulate the heating medium through the substrate support pedestal. As a result, the substrate W is heated, and the first film is etched. At this time, the controller Cnt may control the DC power supply 12b to supply power to the thermoelectric element SP1a so that the temperature of the thermoelectric element SP1a on the side of the substrate support part WS is increased. After etching the first film, the second film is etched. The controller Cnt controls the DC power supply 12b such that the temperature of the thermoelectric element SP1a on the side of the substrate support part WS becomes a low temperature (heat absorption). Further, the controller Cnt switches the medium source to the second chiller 107b so as to circulate the cooling medium through the substrate support pedestal. As a result, the substrate W is cooled down, and the second film is etched. When etching the second film, the temperature may be adjusted by controlling the current to be supplied to the heater EP2. By using the thermoelectric element SP1a, the first chiller 107a, the second chiller 107b, and the heater EP2, it is possible to control the temperature in a wide temperature range with good responsiveness.

According to the present disclosure in some embodiments, it is possible to control a temperature of a substrate placed on a substrate support pedestal with good responsiveness.

Although various exemplary embodiments have been described above, the present disclosure is not limited to the exemplary embodiments described above, and various omissions, substitutions, and changes may be made. In addition, elements in different exemplary embodiments may be combined to form another exemplary embodiment.

From the foregoing, it should be understood that various exemplary embodiments of the present disclosure have been described herein for purposes of illustration, and that various modifications can be made without departing from the scope and spirit of the present disclosure. Accordingly, the various exemplary embodiments disclosed herein are not intended to be limiting, and the true scope and spirit thereof are represented by the appended claims.

What is claimed is:

1. A substrate support pedestal comprising:
a first metallic member having a recess formed in an upper portion of the first metallic member;
a second metallic member provided on the first metallic member and configured to seal the recess;
a substrate support part provided on the second metallic member; and
one or more thermoelectric elements disposed in the recess,
wherein the recess is filled with a heat transfer medium.

2. The substrate support pedestal of claim 1, wherein the one or more thermoelectric elements are arranged along the substrate support part, and
the one or more thermoelectric elements are arranged at uniform intervals in a circumferential direction of the substrate support part.

3. The substrate support pedestal of claim 2, wherein the one or more thermoelectric elements are arranged more densely at a peripheral edge side than a center of the substrate support part.

4. The substrate support pedestal of claim 3, wherein the first metallic member further includes a flow path through which a first temperature control medium or a second temperature control medium circulates,
the flow path is switchably connected to a first chiller or a second chiller, and
the first temperature control medium supplied from the first chiller and the second temperature control medium supplied from the second chiller have different temperatures.

5. The substrate support pedestal of claim 4, further comprising: a heater electrode.

6. The substrate support pedestal of claim 5, wherein the heater electrode is provided between the substrate support part and the one or more thermoelectric elements.

7. The substrate support pedestal of claim 6, wherein the heat transfer medium is a liquid.

8. The substrate support pedestal of claim 7, wherein the first metallic member includes one or more storage areas,
the one or more storage areas are arranged along the substrate support part, and
the one or more thermoelectric elements are respectively stored in the one or more storage areas together with the heat transfer medium.

9. The substrate support pedestal of claim 8, wherein the second metallic member is provided between the substrate support part and the one or more storage areas, and
the one or more storage areas are defined by the recess and the second metallic member.

10. The substrate support pedestal of claim 9, wherein the one or more thermoelectric elements are fixed to the first metallic member using a heat-conductive adhesive within the recess.

11. The substrate support pedestal of claim 10, wherein the one or more thermoelectric elements are electrically connected in series in a circumferential direction of the substrate support part.

12. The substrate support pedestal of claim 1, wherein the first metallic member further includes a flow path through which a first temperature control medium or a second temperature control medium circulates,
the flow path is switchably connected to a first chiller or a second chiller, and
the first temperature control medium supplied from the first chiller and the second temperature control medium supplied from the second chiller have different temperatures.

13. The substrate support pedestal of claim 1, further comprising: a heater electrode.

14. The substrate support pedestal of claim 1, wherein the heat transfer medium is a liquid.

15. The substrate support pedestal of claim 1, wherein the heat transfer medium is an inert gas.

16. The substrate support pedestal of claim 1, wherein the first metallic member includes one or more storage areas,
the one or more storage areas are arranged along the substrate support part, and
the one or more thermoelectric elements are respectively stored in the one or more storage areas together with the heat transfer medium.

17. The substrate support pedestal of claim 1, wherein the one or more thermoelectric elements are fixed to the first metallic member using a heat-conductive adhesive within the recess.

18. The substrate support pedestal of claim 1, wherein the one or more thermoelectric elements are electrically connected in series in a circumferential direction of the substrate support part.

19. A plasma processing apparatus comprising a substrate support pedestal, wherein the substrate support pedestal includes:
a first metallic member having a recess formed in an upper portion of the first metallic member;
a second metallic member provided on the first metallic member and configured to seal the recess;
a substrate support part provided on the second metallic member; and
one or more thermoelectric elements disposed in the recess,
wherein the recess is filled with a heat transfer medium.
